(19) United States
(12) Patent Application Publication
(10) Pub. No.: US 2019/0181356 A1
(43) Pub. Date: Jun. 13, 2019

(54) ORGANOMETALLIC IRIDIUM COMPLEX, SYNTHETIC METHOD THEREOF, AND ORGANIC LIGHT EMITTING DEVICE USING THE SAME

(71) Applicant: Fu Jen Catholic University, New Taipei City (TW)

(72) Inventors: Win-Long CHIA, Taipei City (TW); Yung-Chi CHEN, Wujie Township (TW)

(21) Appl. No.: 15/894,672

(22) Filed: Feb. 12, 2018

(30) Foreign Application Priority Data
Dec. 11, 2017 (TW) 106143389

(51) Int. Cl. H01L 51/00; C07F 15/00; C09K 11/06

(52) U.S. Cl. CPC H01L 51/0085; C07F 15/0033; H01L 51/5012; C09K 2211/185; C09K 2211/1029; C09K 11/06

(57) ABSTRACT

Provided are an organometallic iridium complex, a synthetic method thereof, and an organic light emitting device using the same. The synthetic method includes steps of: (a) reacting a t-Bu—Ar¹—MgX with a nitrogen-containing heteroaryl salt in a nucleophilic reaction, so as to obtain an intermediate; wherein t-Bu represents a tert-butyl group; Ar¹ is an arylene group having 5 to 16 carbon atoms or a sulfur-containing heteroarylene group having 4 to 14 carbon atoms; X is a halogen atom; the nitrogen-containing heteroaryl salt is a salt which includes the t-Bu—Ar² group, and Ar² is a nitrogen-containing heteroaryl group having 5 to 14 carbon atoms; (b) oxidizing the intermediate with an oxidant for aromatization to obtain a ligand; and (c) reacting the ligand with an iridium(III) acetylacetonate to obtain the organometallic iridium complex. The organometallic iridium complex is represented by the following Formula (I):

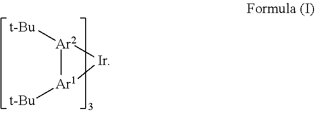

### CROSS-REFERENCE TO RELATED APPLICATION

Pursuant to 35 U.S.C. § 119(a), this application claims the benefits of the priority to Taiwan Patent Application No. 106143389, filed Dec. 11, 2017. The content of the prior application is incorporated herein by its entirety.

### BACKGROUND OF THE INVENTION

### 1. Field of the Invention

The present invention relates to a novel compound, more particularly to an organometallic iridium complex, and a facile synthetic method thereof, and an organic light emitting device using the same.

### 2. Description of the Prior Arts

Organic light emitting devices (OLEDs) exhibit the advantages of their self-emissivity, wide viewing angle, high contrast ratio and high response rate, and thus become the focus of the development of displays. The improvement and development of organometallic compounds as luminescent materials are the key factors in the application and development of OLEDs. Among them, it has been proved that improving the luminescent efficiency of organometallic iridium complexes can help the application of OLEDs.

The ligands of the organometallic iridium complex not only affect the energy gap but also the quantum efficiency thereof. Common ligands for organometallic iridium complex include monocyclic aryl compound, polycyclic aryl compound, or heteroaryl compound.

The conventional syntheses of pyridine-containing compounds involve steps as follows:

(1) cyclization reaction of an enamine compound with a vinyl ketone compound to furnish a dihydropyran derivative, which is then used to react with hydroxylamine hydrochloride to form a pyridine-containing compound;

(2) condensation of an acetophenone with ethyl formate in the presence of sodium, followed by cyclization with cyanoacetamide, substitution of oxygen by chlorine, and then reductive elimination of the chlorine to form a pyridine-containing compound;

(3) cross coupling of arylboronic acids with halopyridines in the presence of a palladium complex to form a pyridine-containing compound; and

(4) reaction of 2,2-dichloro-1-(4-methylphenyl)cyclopropane carbaldehyde with a 4-n-alkoxybenzyl amine at an elevated temperature to form a pyridine-containing compound.

The conventional syntheses of quinoline-containing compounds involve steps as follows:

(1) cyclization of a substituted aniline or benzaldehyde with pyruvic acids, which is followed by decarboxylation of corresponding carboxylic acids to form a quinoline-containing compound;

(2) the Skraup procedure or the Doebner-Von Miller variation in which aniline is reacted with glycerin, 1,2-glycols, or unsaturated aldehydes in the heating environment to form a quinoline-containing compound; and

(3) bis-formylation of acetanilides, followed by cyclization with polyphosphoric acids and subsequent conversion to chloroquinoline aldehydes, which are used as intermediates to synthesize quinoline-containing compounds.

The above methods are available in preparing pyridine-containing compounds or quinoline-containing compounds; however, the conventional methods adopt a relatively expensive catalyst and involve a large number of low-yields synthetic steps, resulting in a low overall yield and high cost. Therefore, the above methods are not suitable for industrial production.

U.S. Pat. No. 7,465,802 B2 discloses a facile synthesis of a series of 2-(4′-alkylphenyl)-5-cyanopyridine liquid crystal compounds. Also, U.S. Pat. No. 7,872,143 B2 discloses a facile synthesis of a series of 2-(4′-alkoxyphenyl)-5-cyanopyridine liquid crystal compounds. However, the above-mentioned patents are especially directed to the synthetic methods of liquid crystals, and the substituents to the pyridine liquid crystal compounds are limited to linear alkyl groups or alkoxy groups. The patents do not teach the method can be used for the synthesizing the ligands of the organometallic complexes, much less the organometallic complexes for OLEDs.

To overcome the shortcomings, the present invention provides a facile method to synthesize novel organometallic iridium complexes to mitigate or obviate the aforementioned problems.

### SUMMARY OF THE INVENTION

An objective of the present invention is to provide a facile method to synthesize a novel organometallic iridium complex with increased synthetic yield, so as to increase potentiality of the OLED products for development.

To achieve the foresaid objective, the present invention provides a synthetic method of making an organometallic iridium complex including steps (a) to (c). In step (a), react a t-Bu—Ar¹—MgX with a nitrogen-containing heteroaryl salt in a nucleophilic reaction, so as to obtain an intermediate. Wherein, “t-Bu” represents a tert-butyl group; “Ar¹” is an arylene group having 5 to 16 carbon atoms or a sulfur-containing heteroarylene group having 4 to 14 carbon atoms; “X” is a halogen atom; the nitrogen-containing heteroaryl salt is a salt containing t-Bu—Ar² group, and “Ar²” is a nitrogen-containing heteroaryl group having 5 to 14 carbon atoms. In step (b), oxidize the intermediate with an oxidant for aromatization, so as to obtain a ligand. In step (c), react the ligand with an iridium(III) acetylacetonate (Ir(acac)₃) to obtain an organometallic iridium complex.

With improved electrophilicity, the nitrogen-containing heteroaryl salt can be reacted with the high selective t-Bu—Ar¹—MgX in a nucleophilic reaction to obtain the intermediate in a high yield. Then, the intermediate is oxidized with the oxidant to obtain the ligand containing nitrogen-containing heteroaryl substitution. The technical means of the present invention can drastically reduce the steps for synthesizing the ligand and increase the synthetic yield of the ligand. Therefore, the overall yield of the organometallic iridium complex can be also increased.

Moreover, the aromatic rings of the ligand used in the present invention all contain tert-butyl groups, and the organometallic iridium complex of the present invention has an iridium metal center chelated by the ligand with an outer shell formed by the tert-butyl groups. The outer shell of the tert-butyl groups can prevent other species in excited state, such as hosts or other fluorescent dyes, from approaching the organometallic iridium complex, such that the organometallic iridium complex of the present invention has the properties of rigidity, bulky volume, hydrophobicity and high solubility for organic compounds. Therefore, the organometallic iridium complex of the present invention has high quantum efficiency and good stability, i.e., insensitive to the change of the surrounding environment; and moreover, the organometallic iridium complex of the present invention can remarkably suppress the decay of the luminous efficiency at high current density.

The reaction time is related to the moles of reactants. Preferably, a molar ratio of the ligand to iridium(III) acetylacetonate in the step (c) is 3:1 to 10:1.

Also, a temperature of the reaction may affect the reaction time. Preferably, the temperature of the reaction in the step (c) ranges from 150° C. to 300° C. More preferably, the temperature of the reaction in the step (c) ranges from 200° C. to 270° C.

Preferably, the oxidant in the step (b) is tetrachloro-o-benzoquinone. Being free of rare metals, the use of tetrachloro-o-benzoquinone also can reduce the costs.

Preferably, the foresaid step (a) comprises step (a1): reacting a t-Bu—Ar¹—X with magnesium granules to obtain the t-Bu—Ar¹—MgX; step (a2): reacting a nitrogen-containing heteroaryl compound with the tert-butyl group and a phenyl chloroformate to obtain the nitrogen-containing heteroaryl salt; and step (a3): performing the nucleophilic reaction of the t-Bu—Ar¹—MgX with the nitrogen-containing heteroaryl salt to obtain the intermediate. Wherein, “X” may be a chlorine atom, a bromine atom or an iodine atom.

Preferably, “Ar¹” is selected from the group consisting of: a phenylene group, a naphthylene group, a biphenylene group, a 9,9-dimethyl-9H-fluorenylene group, a benzothiophenylene group, and a thiophenylene group.

Preferably, the nitrogen-containing heteroaryl salt is selected from the group consisting of: a pyridinium salt with the tert-butyl group, a quinolinium salt with the tert-butyl group, and an isoquinolinium salt with the tert-butyl group.

The present invention also provides an organometallic iridium complex represented by the following Formula (I):

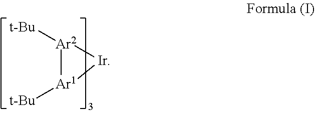

In Formula (I), “Ar¹” is an arylene group having 5 to 16 carbon atoms or a sulfur-containing heteroarylene group having 4 to 14 carbon atoms.

In Formula (I), “Ar²” is a nitrogen-containing heteroarylene group having 5 to 14 carbon atoms.

In Formula (I), “t-Bu” is a tert-butyl group.

As described above, the ligand containing in the organometallic iridium complex is modified with tert-butyl groups, the organometallic iridium complex of the present invention has an iridium metal as core and the tert-butyl groups as the outer shell surrounding the core. Hence, the organometallic iridium complex with the tert-butyl groups shell can have the properties of rigidity, bulky volume, hydrophobicity and high solubility for organic compounds. Therefore, the organometallic iridium complex of the present invention has high quantum efficiency and good stability, and it can remarkably restrain the attenuation level of luminous efficiency.

In accordance with the present invention, the organometallic iridium complex represented by the Formula (I) is synthesized by the foresaid synthetic method.

In accordance with the present invention, “Ar²” could be any kind of nitrogen-containing heteroarylene group having 5 to 14 carbon atoms.

Preferably, the organometallic iridium complex may be represented by any one of the following Formulae:

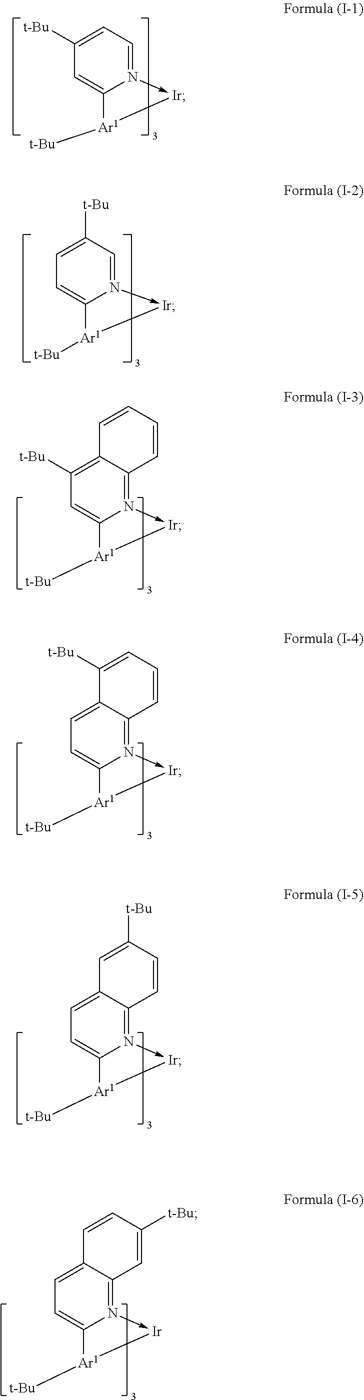

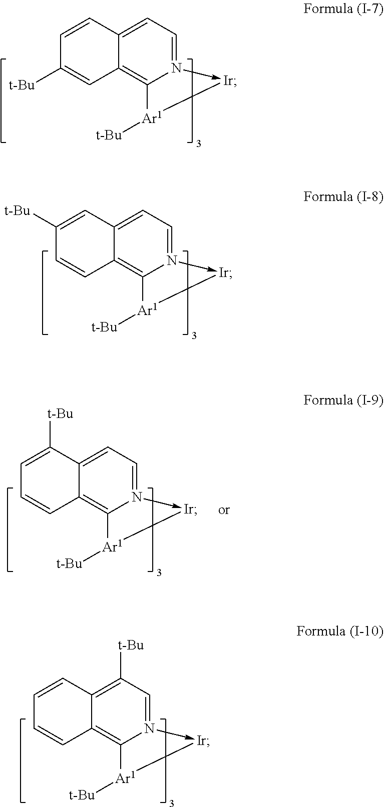

wherein “Ar¹” is an arylene group having 5 to 16 carbon atoms or a sulfur-containing heteroarylene group having 4 to 14 carbon atoms.

In accordance with the present invention, “Ar¹” could be any kind of arylene group having 5 to 16 carbon atoms and sulfur-containing heteroarylene group having 4 to 14 carbon atoms.

Preferably, the organometallic iridium complex may be represented by any one of the following Formulae:

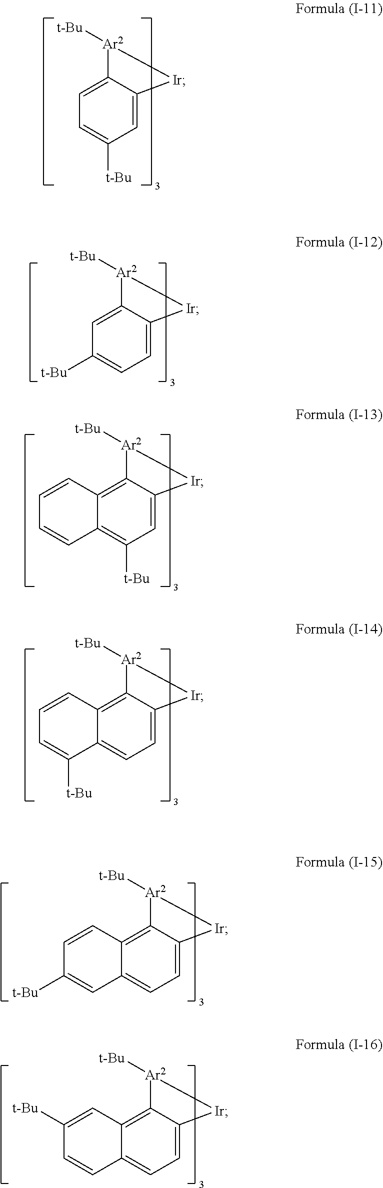

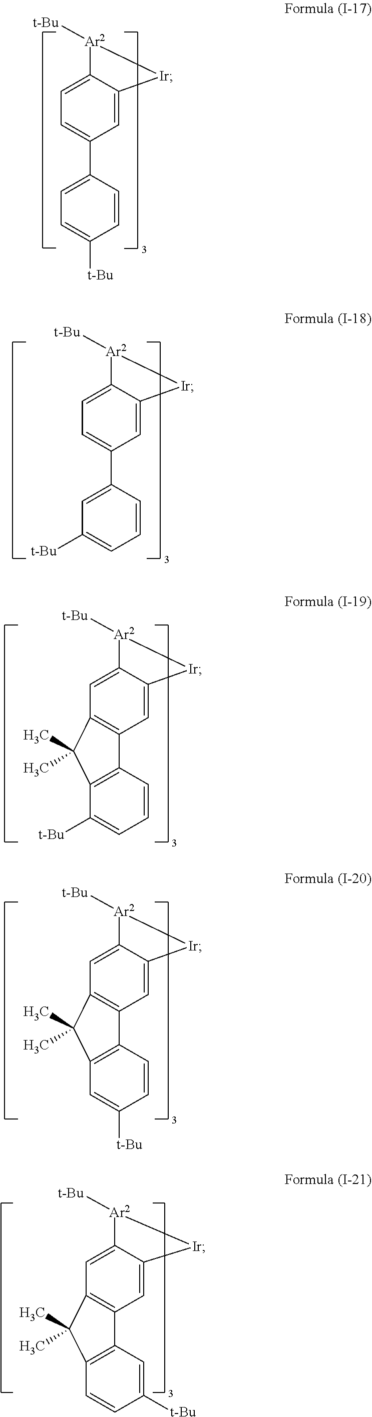

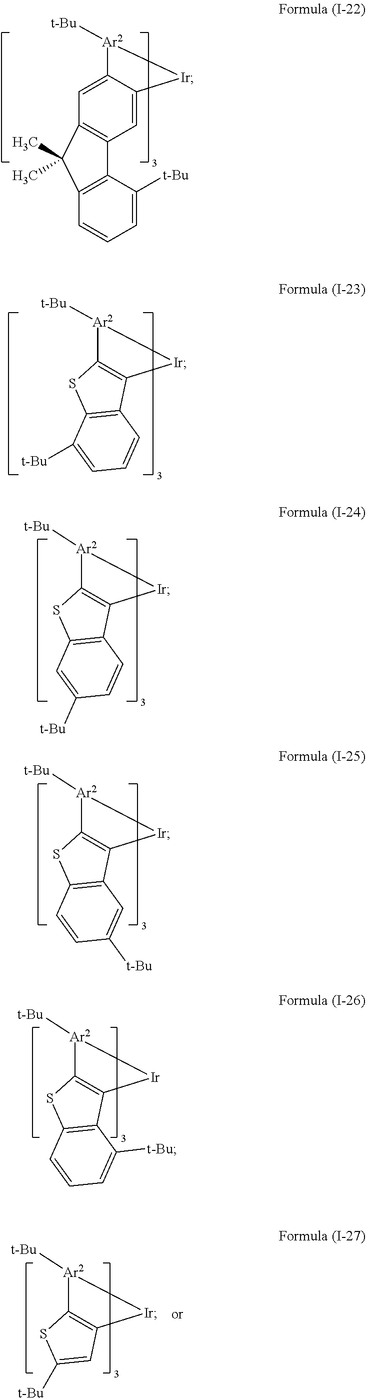

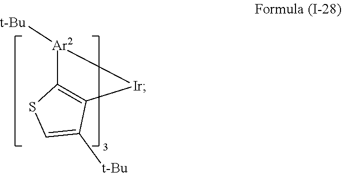

wherein “Ar²” is a nitrogen-containing heteroarylene group having 5 to 14 carbon atoms.

The present invention also provides an organic light emitting device, comprising a first electrode, a second electrode, and an organic layer disposed between the first electrode and the second electrode. The organic layer comprises the novel organometallic iridium complex as described above.

Other objectives, advantages and novel features of the invention will become more apparent from the following detailed description when taken in conjunction with the accompanying drawings.

### BRIEF DESCRIPTION OF THE DRAWINGS

FIG. 1 is ¹H-nuclear magnetic resonance (NMR) spectrum of Ligand 1.

FIG. 2 is ¹³C-NMR spectrum of Ligand 1.

FIG. 3 is ¹H-NMR spectrum of Organometallic iridium complex 1.

FIG. 4 is ¹³C-NMR spectrum of Organometallic iridium complex 1.

### DETAILED DESCRIPTION OF THE PREFERRED EMBODIMENTS

Hereinafter, one skilled in the arts can easily realize the advantages and effects of the present invention from the following examples. It should be understood that the descriptions proposed herein are just preferable examples only for the purpose of illustrations, not intended to limit the scope of the invention. Various modifications and variations could be made in order to practice or apply the present invention without departing from the spirit and scope of the invention.

### Synthesis of Organometallic Iridium Complexes

In the following examples, ¹H-NMR and ¹³C-NMR spectra were recorded on Bruker AC 300 NMR spectrometer to identify the chemical structures of ligands and organometallic iridium complexes. Column chromatography was carried out with silica gel (MN Kieselgel 60, 70 mesh to 230 mesh; Duren, Germany). Purity of products was checked by thin-layer chromatography (TLC) and further confirmed by elemental analysis.

Pre-treatment for the raw materials:

1. phenyl chloroformate: distilled under an inert nitrogen atmosphere immediately before use;

2. triglycerol: distilled under vacuum before use;

3. toluene: heated at reflux over sodium and then distilled under nitrogen before use; and

4. tetrahydrofuran (THF): heated at reflux over sodium and then distilled under nitrogen before use.

### EXAMPLE 1

### Synthesis of Intermediate 1

Intermediate 1 used for preparing Ligand 1 was synthesized by the following steps. The synthesis pathway of the Intermediate 1 was summarized in Scheme A1.

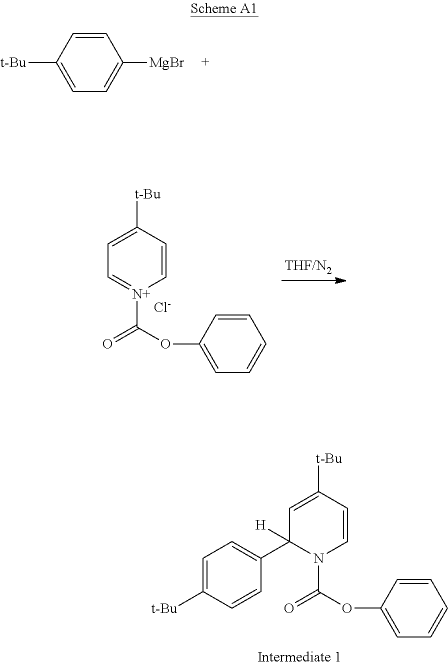

First, in step (a1), a mixed solution was formed by solving 10 mmol 4-tert-butylphenylbromide in 20 mL THF. Then, freshly dried magnesium granules (11 mmol) were added into the mixed solution under an inert nitrogen atmosphere for about half an hour to obtain a 4-tert-butylphenyl magnesium bromide as a Grignard reagent.

In step (a2), 4-tert-butylpyridine (10 mmol) was reacted with phenyl chloroformate (10 mmol) in 20 mL dry THF at −20° C. for half of an hour to obtain 4-tert-butylpyridinium chloride.

In step (a3), the solution of 4-tert-butylphenyl magnesium bromide was then slowly added with a syringe into the solution of 4-tert-butylpyridinium chloride, and the foresaid reaction mass was slowly heated to room temperature and stirred for additional 8 hours to perform the nucleophilic reaction. After completion of the reaction, the solvent THF was evaporated, and the residue was extracted with diethyl ether (Et₂O) and then separated organic phase. The organic phase was further washed once with 20% ammonium chloride solution and twice with distilled water and brine, and finally was dried with magnesium sulfate to obtain Intermediate 1.

### Synthesis of Ligand 1

Ligand 1 used for preparing Organometallic iridium complex 1 was synthesized by the following steps. The synthesis pathway of the Ligand 1 was summarized in Scheme A2.

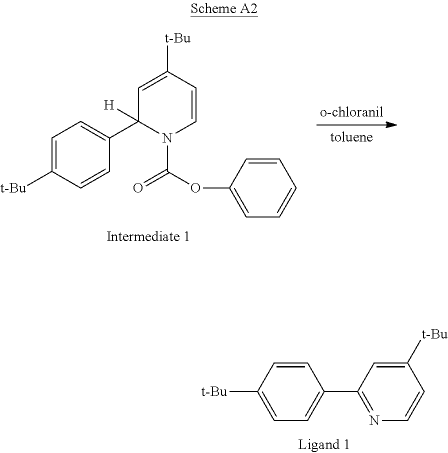 [SMILES: CC(C)(C)C1=CC(c2ccc(C(C)(C)C)cc2)N(C(=O)Oc2ccccc2)C=C1 ; CC(C)(C)c1ccc(-c2cc(C(C)(C)C)ccn2)cc1]

In step (b), the Intermediate 1 (10 mmol) was dissolved in 20 mL dry toluene, and then o-chloranil (1.3 eq.) as an oxidant was added into the toluene solution to oxidize the Intermediate 1. The foresaid reaction mass was heated to reflux for about 3 hours under inert nitrogen atmosphere, and then quenched by adding 1 N NaOH (25 mL) and Et₂O (25 mL). A crude product was filtered by Celite (Duren, Germany). The crude product was purified by column chromatography on silica gel with eluent (the volume ratio of hexane to ethyl acetate is 18:1). Finally, pure colorless liquid of Ligand 1 (4-tert-butyl-2-(4-tert-butylphenyl)pyridine) was obtained by distillation under reduced pressure using bulb-to-bulb micro-distillation apparatus. Ligand 1 was obtained in 75% overall yield, from steps (a1) to (b).

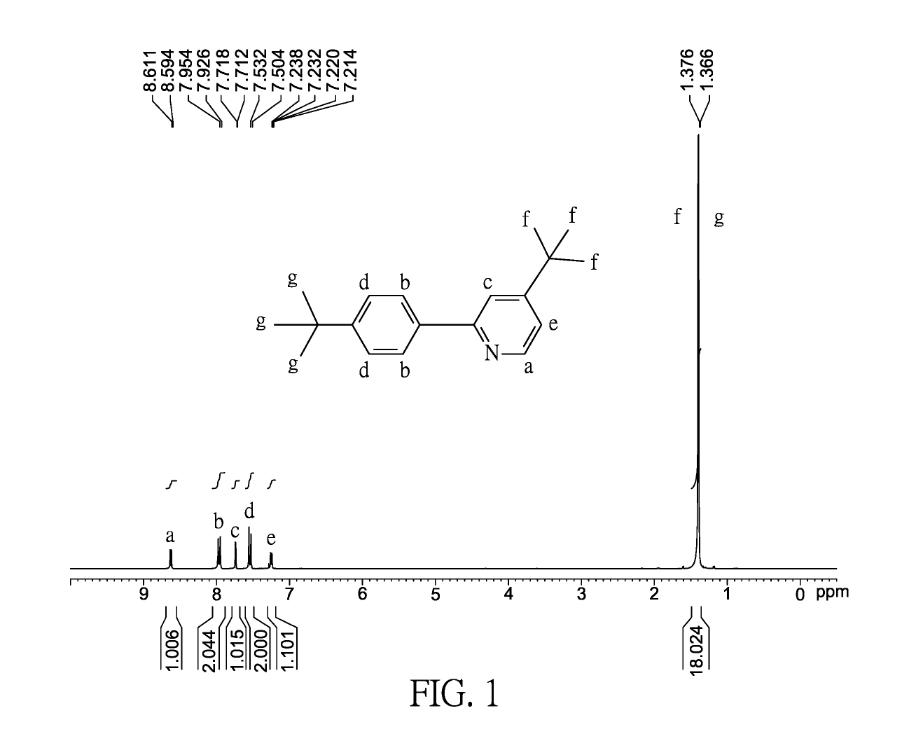

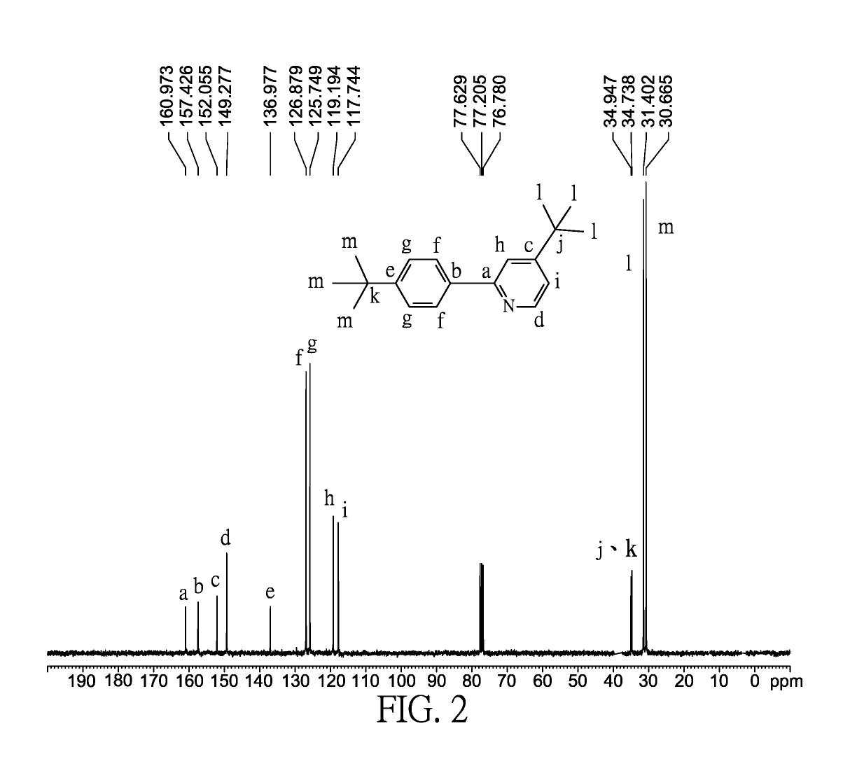

The chemical structure of Ligand 1 gave satisfactory ¹H-NMR as shown in FIG. 1, ¹³C-NMR as shown in FIG. 2, and elemental analysis results as listed below.

¹H-NMR (CDCl₃): δ 8.60 (d, J=5.1 Hz, 1H of pyridine as label a in FIG. 1), 7.94 (d, J=8.4 Hz, 2H of benzene as label b in FIG. 1), 7.72 (d, J=1.8 Hz, 1H of pyridine as label c in FIG. 1), 7.52 (d, J=8.4 Hz, 2H of benzene as label d in FIG. 1), 7.22 (dd, J₁=5.4 Hz, J₂=1.8 Hz, 1H of pyridine as label e in FIG. 1), 1.38 (s, 9H of tert-butyl on pyridine as label f in FIG. 1), 1.37 (s, 9H of tert-butyl on benzene as label g in FIG. 1).

¹³C-NMR (CDCl₃): ppm 160.97 (label a in FIG. 2), 157.43 (label b in FIG. 2), 152.06 (label c in FIG. 2), 149.28 (label d in FIG. 2), 136.98 (label e in FIG. 2), 126.88 (label f in FIG. 2), 125.75 (label g in FIG. 2), 119.19 (label h in FIG. 2), 117.74 (label i in FIG. 2), 34.95 (label j in FIG. 2), 34.74 (label k in FIG. 2), 31.40 (label l in FIG. 2), 30.67 (as label m in FIG. 2).

Ligand 1 was identified by element analysis. Analysis calculated for C₁₉H₂₅N: C, 85.34; H, 9.42; N, 5.24. Found: C, 84.62; H, 9.38; N, 5.18.

### Synthesis of Organometallic Iridium Complex 1

The synthesis pathway of the Organometallic iridium complex 1 was summarized in Scheme B.

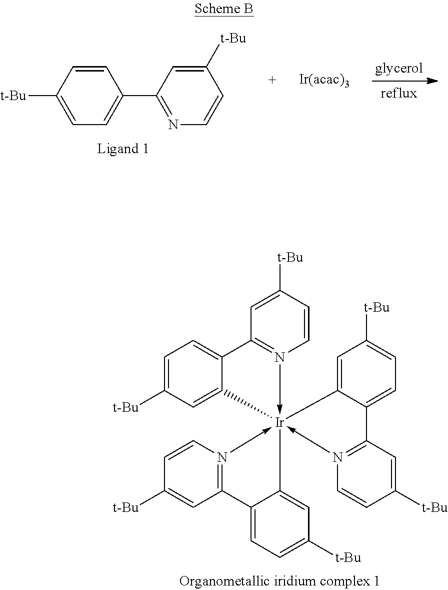

In step (c), Ir(acac)₃ (1.02 g, 2.09 mmol) was dissolved in 20 mL degassed glycerol. Distilled Ligand 1 (2.6 g, 9.72 mmol) was added into the foresaid glycerol solution under an inert nitrogen atmosphere. The foresaid glycerol solution was then heated up to 250° C. and refluxed for additional 6 hours. Yellowish oily solid product was collected on a glass filter frit after cooling. The yellowish oily solid product was further purified by using silica gel column with methylene chloride as eluent to obtain brightly yellowish-green powders as crude product. The yield of the crude product was almost 100%. Pure yellowish-green crystals of Organometallic iridium complex 1 were obtained by recrystallization with mixing solvents of methylene chloride and methanol.

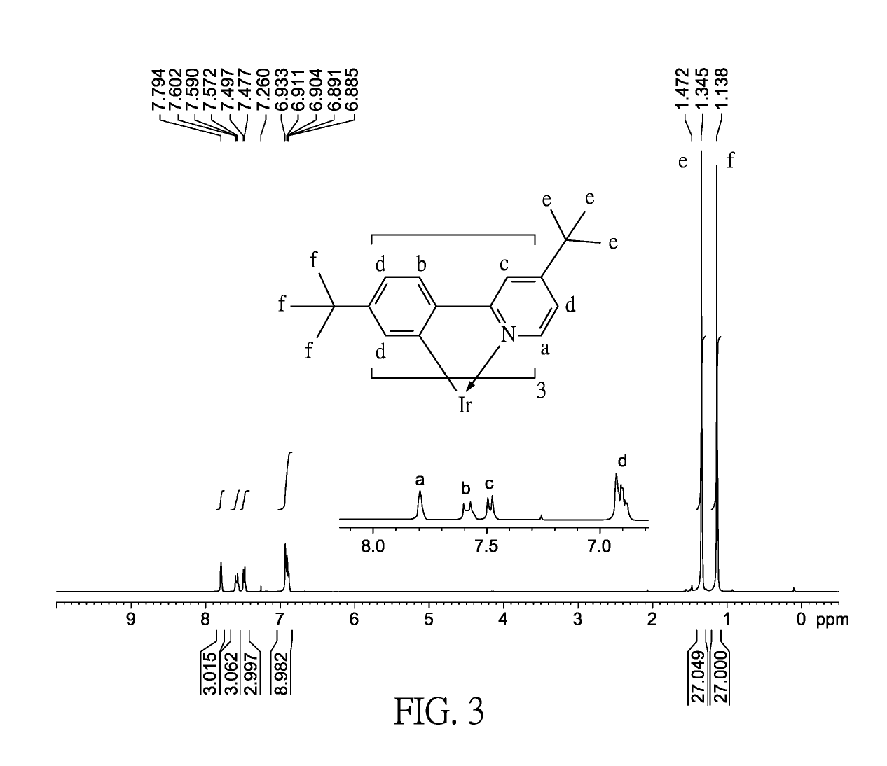

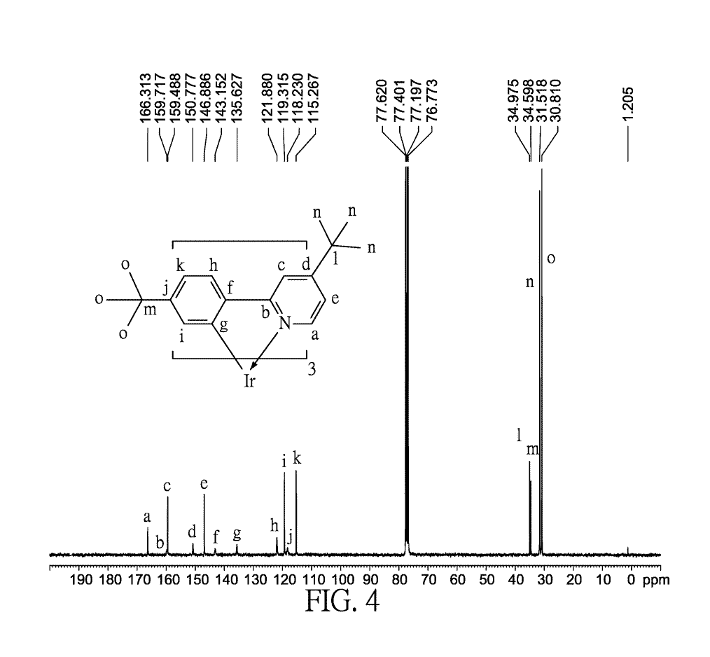

The chemical structure of Organometallic iridium complex 1 gave satisfactory ¹H-NMR as shown in FIG. 3, ¹³C-NMR as shown in FIG. 4, and elemental analysis results as listed below.

¹H-NMR (CDCl₃): δ 7.80 (s, 3H of pyridine as label a in FIG. 3), 7.57-7.60 (m, 3H of benzene as label b in FIG. 3), 7.47-7.50 (m, 3H of pyridine as label c in FIG. 3), 6.88-6.93 (m, 9H of 6H in benzene and 3H in pyridine as label d in FIG. 3), 1.35 (s, 27H of tert-butyl on pyridine as label e in FIG. 3), 1.14 (s, 27H of tert-butyl on benzene as label f in FIG. 3).

¹³C-NMR (CDCl₃): ppm 166.31 (label a in FIG. 4), 159.72 (label b in FIG. 4), 159.49 (label c in FIG. 4), 150.78 (label d in FIG. 4), 146.89 (label e in FIG. 4), 143.15 (label f in FIG. 4), 135.63 (label g in FIG. 4), 121.88 (label h in FIG. 4), 119.32 (label i in FIG. 4), 118.23 (label j in FIG. 4), 115.27 (label k in FIG. 4), 34.98 (label l in FIG. 4), 34.60 (label m in FIG. 4), 31.52 (label n in FIG. 4), 30.81 (label o in FIG. 4).

Organometallic iridium complex 1 was identified by element analysis. Analysis calculated for IrC₅₇H₇₂N₃: C, 69.05; H, 7.32; N, 4.24. Found: C, 68.99; H, 7.27; N, 4.29.

The structure of Ligand 1 and Organometallic iridium complex 1 in Example 1 according to the above synthesis method is as follows:

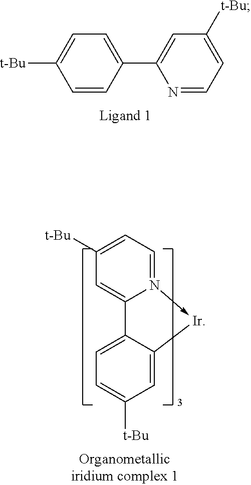

### EXAMPLE 2

Ligand 2 (2,6-tert-butyl-2-(4-tert-butylphenyl)quinolone) used for preparing an Organometallic iridium complex 2 was synthesized in a similar manner as Ligand 1 through steps (a1) to (a3) and step (b), except that the material 4-tert-butylpyridine was replaced by 6-tert-butylquinoline in step (a2), and the eluent (the volume ratio of hexane to ethyl acetate is 18:1) was replaced by the eluent (the volume ratio of hexane to ethyl acetate is 16:1) in step (b).

The yield of the crude product of Ligand 2 is about 65%. Pure white crystals of Ligand 2 were obtained by recrystallization with mixing solvents of methylene chloride and hexane.

The chemical structure of Ligand 2 gave satisfactory ¹H-NMR, ¹³C-NMR, and elemental analysis results as listed below.

¹H-NMR (CDCl₃): δ 8.17 (d, J=8.7 Hz, 1H of quinoline), 8.13 (d, J=9.0 Hz, 1H of quinoline), 8.10 (d, J=8.4 Hz, 2H of benzene), 7.84 (d, J=8.7 Hz, 1H of quinoline), 7.83 (dd, J₁=9.0 Hz, J₂=2.1 Hz 1H of quinoline), 7.74 (d, J=2.1 Hz, 1H of quinoline), 7.56 (d, J=8.4 Hz, 2H of benzene), 1.46 (s, 9H of tert-butyl on pyridine), 1.40 (s, 9H of tert-butyl on benzene).

¹³C-NMR (CDCl₃): ppm 156.98, 152.44, 149.08, 147.05, 137.32, 136.75, 129.40, 128.65, 127.37, 126.94, 125.94, 122.58, 119.03, 35.07, 34.88, 31.48, 31.41.

Ligand 2 was identified by element analysis. Analysis calculated for C₂₃H₂₇N: C, 87.02; H, 8.57; N, 4.41. Found: C, 86.95; H, 8.59; N, 4.43.

Organometallic iridium complex 2 was synthesized in a similar manner as Organometallic iridium complex 1 through step (c), except that the material Ligand 1 was replaced by Ligand 2. The yield of Organometallic iridium complex 2 is about 20%.

The chemical structure of Organometallic iridium complex 2 gave satisfactory ¹H-NMR, ¹³C-NMR, and elemental analysis results as listed below.

¹H-NMR (CDCl₃): δ 7.99-8.03 (m, 6H of quinoline), 7.94 (d, J=9.0 Hz, 3H of benzene), 7.65 (d, J=8.4 Hz, 3H of quinoline), 7.57 (d, J=2.4 Hz, 3H of quinoline), 6.85 (dd, J₁=8.1 Hz, J₂=2.1 Hz, 3H of quinoline), 6.75 (dd, J₁=9.0 Hz, J₂=2.1 Hz, 3H of benzene), 6.32 (d, J=1.8 Hz, 3H of benzene), 1.24 (s, 27H of tert-butyl on pyridine), 0.94 (s, 27H of tert-butyl on benzene).

¹³C-NMR (CDCl₃): ppm 166.37, 160.51, 151.61, 147.74, 147.65, 143.24, 136.74, 133.13, 128.00, 127.96, 127.42, 124.78, 123.38, 117.79, 116.78, 34.62, 34.32, 31.37, 31.26.

Organometallic iridium complex 2 was identified by element analysis. Analysis calculated for IrC₆₉H₇₈N₃: C, is 72.59; H, 6.89; N, 3.68. Found: C, 72.37; H, 6.83; N, 3.7.

The structure of Ligand 2 and Organometallic iridium complex 2 in Example 2 according to the above synthesis method is as follows:

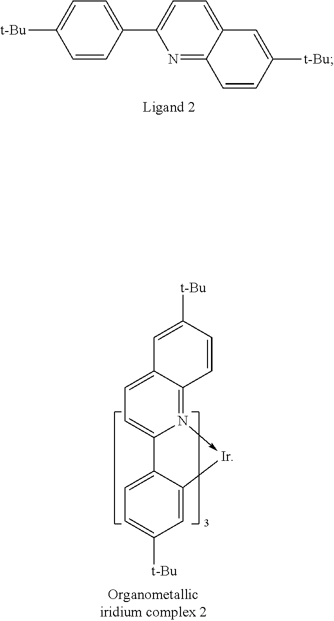

### EXAMPLE 3

Ligand 3 (4-(tert-butyl)-2-(4′-(tert-butyl)-[1,1′-biphenyl]-4-yl)pyridine) used for preparing an Organometallic iridium complex 3 was synthesized in a similar manner as Ligand 1 through steps (a1) to (a3) and step (b), except that the material 4-tert-butylphenylbromide was replaced by 4-bromo-4′-(tert-butyl)-1,1′-biphenyl in step (a1), and the eluent (the volume ratio of hexane to ethyl acetate is 18:1) was replaced by the eluent (the volume ratio of hexane to ethyl acetate is 8:1) in step (b).

The yield of the crude product of Ligand 3 is about 70%. And pure white crystals of Ligand 3 were obtained by recrystallization with mixing solvents of methylene chloride and methanol.

The chemical structure of Ligand 3 gave satisfactory ¹H-NMR, ¹³C-NMR, and elemental analysis results as listed below.

1H-NMR (CDCl₃): δ 8.62 (d, J=5.1 Hz, 1H of pyridine), 8.06 (d, J=8.4 Hz, 2H of benzene), 7.76 (d, J=1.2 Hz, 1H of pyridine), 7.72 (d, J=8.4 Hz, 2H of benzene), 7.63 (d, J=8.7 Hz, 2H of benzene), 7.50 (d, J=8.7 Hz, 2H of benzene), 7.25 (dd, J₁=5.1 Hz, J₂=1.8 Hz, 1H of pyridine), 1.39 (s, 9H of tert-butyl on pyridine), 1.38 (s, 9H of tert-butyl on benzene).

13C-NMR (CDCl₃): 160.85, 157.34, 150.69, 149.75, 141.47, 138.80, 137.89, 127.54, 127.40, 126.90, 125.94, 119.47, 117.77, 35.03, 34.73, 31.53, 30.78.

Ligand 3 was identified by element analysis. Analysis calculated for C₂₅H₂₉N: C, 87.41; H, 8.51; N, 4.08. Found: C, 87.41; H, 8.55; N, 4.01.

Organometallic iridium complex 3 was synthesized in a similar manner as Organometallic iridium complex 1 through step (c), except that the material Ligand 1 was replaced by Ligand 3. The yield of Organometallic iridium complex 3 is about 100%.

The chemical structure of Organometallic iridium complex 3 gave satisfactory ¹H-NMR, ¹³C-NMR, and elemental analysis results as listed below.

¹H-NMR (CDCl₃): δ 7.84 (s, 3H of pyridine), 7.70 (d, J=8.1 Hz, 3H of center-benzene), 7.46 (d, J=6.3 Hz, 3H of pyridine), 7.40 (d, J=8.4 Hz, 6H of benzene), 7.29 (d, J=8.1 Hz, 6H of benzene), 7.26 (s, 3H of center-benzene), 7.14 (d, J=7.5 Hz, 3H of center-benzene), 6.87 (d, J=6.3 Hz, 3H of pyridine), 1.32 (s, 27H of tert-butyl on pyridine), 1.29 (s, 27H of tert-butyl on benzene).

¹³C-NMR (CDCl₃): 166.18, 162.10, 159.63, 149.38, 146.76, 143.62, 140.96, 139.63, 135.59, 126.87, 125.55, 124.00, 119.44, 118.79, 115.66, 35.07, 34.58, 31.56, 30.76.

Organometallic iridium complex 3 was identified by element analysis. Analysis calculated for IrC₇₅H₈₄N₃: C, 73.85; H, 6.94; N, 3.45. Found: C, 72.3; H, 6.81; N, 3.35.

The structure of Ligand 3 and Organometallic iridium complex 3 in Example 3 according to the above synthesis method is as follows:

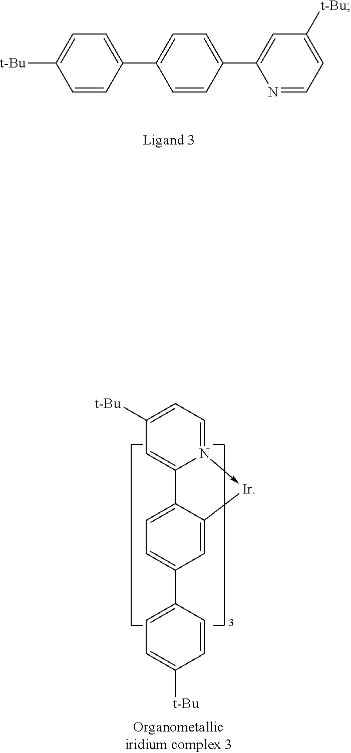

The above examples are merely illustrative of the synthetic method of making the organometallic iridium complex. One skilled in the art can select various suitable t-Bu—Ar^{l}—MgX and nitrogen-containing heteroaryl salts to undergo the nucleophilic reaction. The process parameters in the reaction can be adjusted to synthesize any organometallic iridium complexes of the present invention.

According to the synthetic method of making the organometallic iridium complex, the organometallic iridium complex can be used as a luminescent material in organic light-emitting devices such as OLEDs, so as to enhance the light-emitting efficiency of the organic light-emitting device.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A synthetic method of making an organometallic iridium complex, comprising steps of:
step (a): reacting a t-Bu—Ar¹—MgX with a nitrogen-containing heteroaryl salt in a nucleophilic reaction, so as to obtain an intermediate;
wherein t-Bu represents a ten-butyl group; Ar¹ is an arylene group having 5 to 16 carbon atoms or a sulfur-containing heteroarylene group having 4 to 14 carbon atoms; X is a halogen atom; the nitrogen-containing heteroaryl salt is a salt which includes t-Bu—Ar² group, and Ar² is a nitrogen-containing heteroaryl group having 5 to 14 carbon atoms;
step (b): oxidizing the intermediate with an oxidant for aromatization, so as to obtain a ligand; and
step (c): reacting the ligand with an iridium(III) acetylacetonate to obtain the organometallic iridium complex.

2. The synthetic method as claimed in claim 1, wherein a molar ratio of the ligand to the iridium(III) acetylacetonate in the step (c) is 3:1 to 10:1.

3. The synthetic method as claimed in claim 1, wherein a temperature of the reaction in the step (c) ranges from 150° C. to 300° C.

4. The synthetic method as claimed in claim 3, wherein the temperature of the reaction in the step (c) ranges from 200° C. to 270° C.

5. The synthetic method as claimed in claim 1, wherein the oxidant in the step (b) is tetrachloro-o-benzoquinone.

6. The synthetic method as claimed in claim 1, wherein the step (a) comprises:
step (a1): reacting a t-Bu—Ar¹—X with magnesium granules to obtain the t-Bu—Ar¹—MgX, wherein X is a chlorine atom, a bromine atom or an iodine atom;
step (a2): reacting a nitrogen-containing heteroaryl compound with a tert-butyl group and a phenyl chloroformate to obtain the nitrogen-containing heteroaryl salt; and
step (a3): reacting the t-Bu—Ar¹—MgX with the nitrogen-containing heteroaryl salt in the nucleophilic reaction, so as to obtain the intermediate.

7. The synthetic method as claimed in claim 1, wherein Ar¹ is selected from the group consisting of: a phenylene group, a naphthylene group, a biphenylene group, a 9,9-dimethyl-9H-fluorenylene group, a benzothiophenylene group, and a thiophenylene group.

8. The synthetic method as claimed in claim 6, wherein Ar¹ is selected from the group consisting of: a phenylene group, a naphthylene group, a biphenylene group, a 9,9-dimethyl-9H-fluorenylene group, a benzothiophenylene group, and a thiophenylene group.

9. The synthetic method as claimed in claim 1, wherein the nitrogen-containing heteroaryl salt is selected from the group consisting of: a pyridinium salt with the tert-butyl group, an quinolinium salt with the tert-butyl group, and an isoquinolinium salt with the tert-butyl group.

10. The synthetic method as claimed in claim 6, wherein the nitrogen-containing heteroaryl salt is selected from the group consisting of: a pyridinium salt with the tert-butyl group, an quinolinium salt with the tert-butyl group, and an isoquinolinium salt with the tert-butyl group.

11. The synthetic method as claimed in claim 8, wherein the nitrogen-containing heteroaryl salt is selected from the group consisting of: a pyridinium salt with the tert-butyl group, an quinolinium salt with the tert-butyl group, and an isoquinolinium salt with the tert-butyl group.

12. An organometallic iridium complex represented by the following Formula (I): 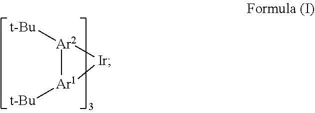
wherein Ar¹ is an arylene group having 5 to 16 carbon atoms or a sulfur-containing heteroarylene group having 4 to 14 carbon atoms;
wherein Ar² is a nitrogen-containing heteroarylene group having 5 to 14 carbon atoms;
wherein t-Bu is a tert-butyl group.

13. The organometallic iridium complex as claimed in claim 12, wherein the organometallic iridium complex is represented by 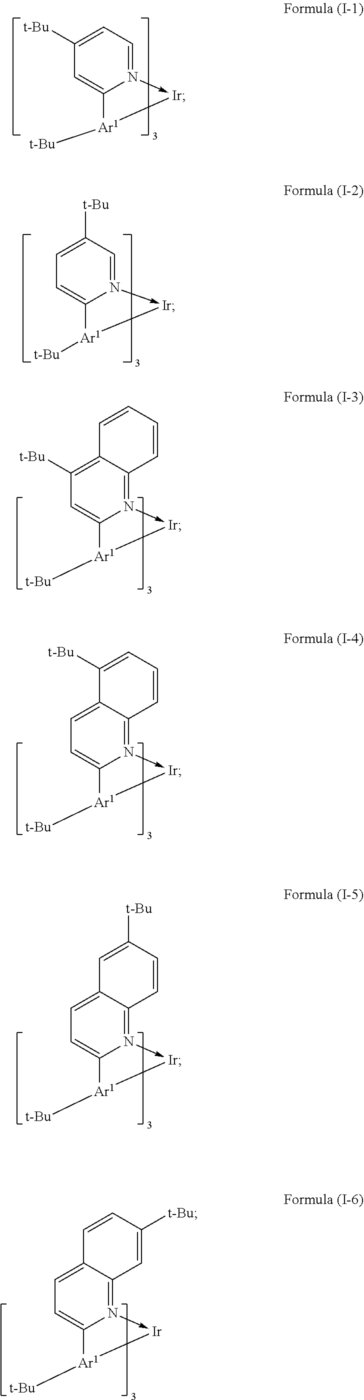 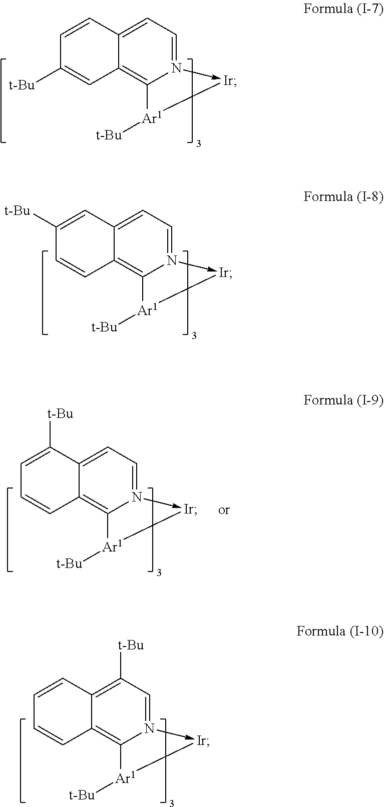
wherein Ar¹ is the arylene group having 5 to 16 carbon atoms or the sulfur-containing heteroarylene group having 4 to 14 carbon atoms.

14. The organometallic iridium complex as claimed in claim 12, wherein the organometallic iridium complex is represented by 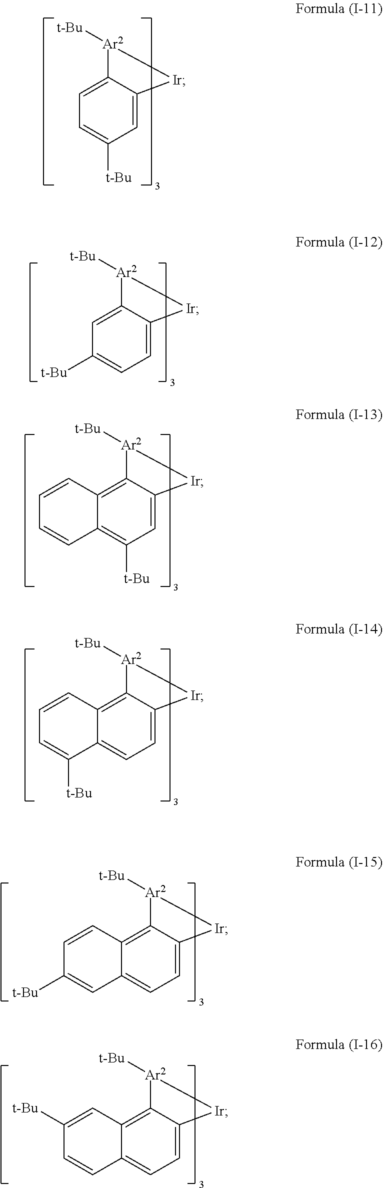 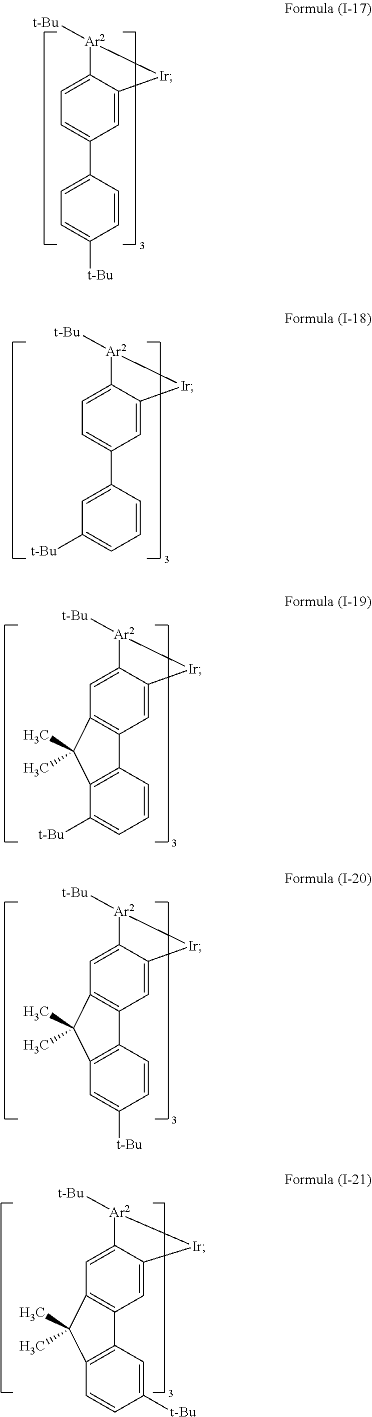 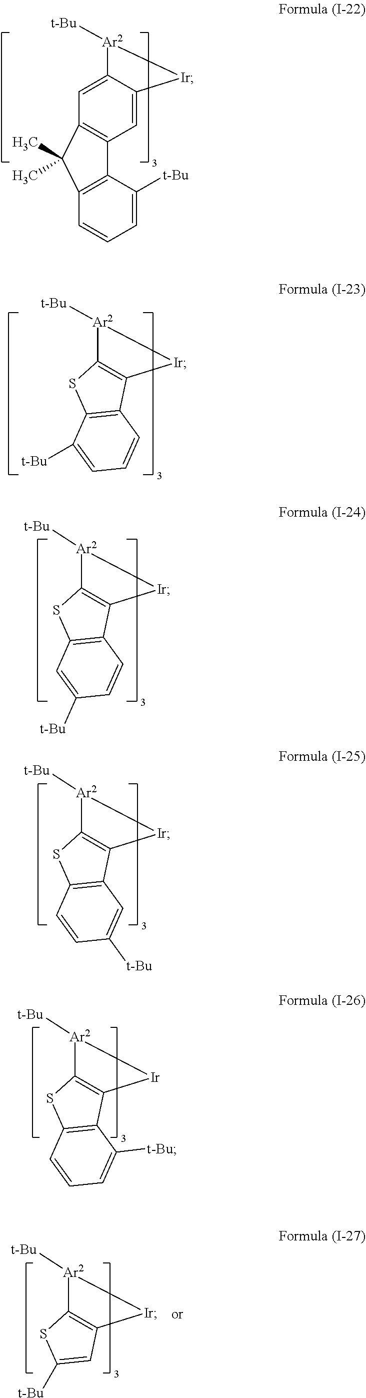 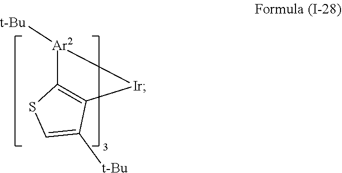
wherein Ar² is the nitrogen-containing heteroarylene group having 5 to 14 carbon atoms.

15. An organic light emitting device, comprising a first electrode, a second electrode, and an organic layer disposed between the first electrode and the second electrode, wherein the organic layer comprises the organometallic iridium complex as claimed in claim 12.
